(19) United States
(12) Patent Application Publication
(10) Pub. No.: US 2013/0043961 A1
(43) Pub. Date: Feb. 21, 2013

(54) DUPLEXER WITH SHIELDING BONDWIRES BETWEEN FILTERS

(71) Applicants: Bernhard Gebauer, Bavaria (DE); Martin Handtmann, Munich (DE)

(72) Inventors: Bernhard Gebauer, Bavaria (DE); Martin Handtmann, Munich (DE)

(73) Assignee: Avago Technologies Wireless IP (Singapore) Pte.Ltd, Singapore (SG)

(21) Appl. No.: 13/209,499

(22) Filed: Aug. 15, 2011

(51) Int. Cl. H03H 9/70

(52) U.S. Cl. 333/133; 174/36

(57) ABSTRACT

A duplexer includes first and second filters, and a first shielding bondwire. The first filter includes a first bondwire connecting the first filter to a printed circuit board, the first bondwire forming a portion of a first virtual loop having a first virtual area, where first current passing through the first bondwire generates a first magnetic field. The second filter includes a second bondwire connecting the second filter to the printed circuit, the second bondwire forming a portion of a second virtual loop having a second virtual area. The first shielding bondwire includes first and second ends connected to a conductor of the printed circuit board to form a closed electrical first shielding loop having a corresponding first shielding area. The magnetic field induces shielding current in the first shielding loop, which generates a first compensating magnetic field that attenuates the first magnetic field.

### BACKGROUND

Portable communication devices, such as cellular telephones, personal digital assistants (PDAs), electronic gaming devices, laptop computers, and the like, are configured to communicate over wireless networks. Accordingly, each such portable communication device includes a transmitter (TX) and a receiver (RX), typically connected to a common antenna, for transmitting and receiving data and control signals over the wireless network. A duplexer is included to enable simultaneous transmission and reception of signals using the common antenna. The duplexer electrically connects the common signal path to the output of the transmitter via a transmit signal path and to the input of the receiver via a separate receive signal path, so that the transmitter is able to send signals on a transmit frequency and the receiver is able to receive signals on a different receive frequency, while substantially isolating the transmitter from the receiver.

A duplexer has three ports. The first port is connected to the antenna, the second port is connected to the transmitter and the third port is connected to the receiver. Transmitted and received signals are assigned to different frequency bands, depending on the relevant communication standard. However, the transmitted and received signals co-exist at the common antenna, as mentioned above. Thus, for the transmission path, the duplexer substantially suppresses signals outside the transmit frequency band, and for the reception path, the duplexer substantially suppresses signals outside the receive frequency band.

More particularly, a duplexer typically includes a transmit filter connected to a transmitter port, a receive filter connected to a receiver port, and a matching circuit connected between each of the transmit filter and the receive filter and the common antenna at an antenna port. The transmit and receive filters are band-pass filters having different passbands for filtering and isolating the transmitted and received signals, respectively. That is, the transmit and receive filters provide low attenuation of signals in the corresponding passbands, and high attenuation of signals in frequency ranges outside of the passbands, i.e., in corresponding stopbands. For purposes of discussion, the transmit or receive filter that is in its passband at a particular frequency may be referred to as the “active filter” at this particular frequency, and the other one of the transmit or receive filter that is in its stopband at the particular frequency may be referred to as the “passive filter” at this particular frequency. Thus, the active filter is associated with a signal being applied to the duplexer in the respective passband, and only performance of the active filter with respect to this signal is analyzed. Generally, isolation between the port connected to the receiver and the port connected to the transmitter relies on the fact that the only significant electrical/signal interaction between the transmitted and received signals occurs at the common antenna. However, undesirable crosstalk may occur elsewhere along the transmit and/or receive signal paths, eventually degrading the isolation.

A filter may include one or more filter stages connected in series between an input port and an output port. For example, referring to a receive filter, all of the filter stages are active in the passband and see full signal amplitude when a signal is applied at the antenna port that has a frequency or frequency spectra in the passband frequency range of the receive filter. In the stopband, each filter stage provides partial attenuation of a signal that has a frequency or frequency spectra in the stopband frequency range of the receive filter, such that total attenuation of the filter between the antenna and receiver ports is the aggregate of the partial attenuations provided by each filter stage. Therefore, when undesired crosstalk, which has a frequency or frequency spectra in the stopband frequency range of the receive filter, between the transmit filter and the receive filter of the duplexer affects a filter stage close to the antenna port, some attenuation is still provided by subsequent filter stages with respect to the receiver port. However, when the crosstalk affects a filter stage close to the receiver port of the receive filter, the attenuation of the parasitic signal from the crosstalk will be low (or zero) with respect to the receiver port. Similarly, the filter stages close to the transmitter port are sensitive to cross-talk. Notably, the origin of such crosstalk may be any stage of the “other” filter, if this other filter is active and thus all of its corresponding filter stages see the full signal amplitude. Consequently, undesirable crosstalk in a conventional duplexer especially degrades isolation performance when a filter stage of the active filter couples to a receiver port or transmitter port filter stage.

One type of undesirable crosstalk is magnetic crosstalk, which applies to filters connected to a substrate using wirebond technology. A wirebonded active filter generates a surrounding or driving magnetic field due to currents in the different bondwires. The magnetic fields may differ depending on signal frequency, since amplitudes and phase relations of the bondwire currents vary across the passband. More particularly, the magnetic field of the active filter may induce a voltage signal in one or more bondwires of the passive filter, and consequently create the magnetic crosstalk. As discussed above, the magnetic crosstalk tends to be more severe when it affects a bondwire that is connected to a filter stage close to the receiver/transmitter port. The worst case typically occurs in an affected bondwire that directly connects the receiver/transmitter port to the filter.

Moving the transmit and receive filters further away from one another helps to reduce the affects of magnetic crosstalk. However, demand for smaller, less expensive and more efficient portable communication devices generally requires the transmit and receive filters to be closer together. Thus, some conventional duplexers include a metallic housing around the transmit and/or receive filter, physically separating the transmit and receive filters, to provide magnetic isolation. However, fabricating a metallic housing is expensive and may otherwise be incompatible with mount technologies typically used in the manufacturing of duplexers with wirebonded filters, and thus time consuming and inconvenient to implement.

### SUMMARY

In a representative embodiment, a duplexer includes first and second filters, and a first shielding bondwire. The first filter includes a first bondwire connecting the first filter to a printed circuit board, the first bondwire forming a portion of a first virtual loop having a first virtual area, where first current passing through the first bondwire generates a first magnetic field. The second filter includes a second bondwire connecting the second filter to the printed circuit, the second bondwire forming a portion of a second virtual loop having a second virtual area. The first shielding bondwire includes first and second ends connected to a conductor of the printed circuit board to form a closed electrical first shielding loop having a corresponding first shielding area. The magnetic field induces shielding current in the first shielding loop, which generates a first compensating magnetic field that attenuates the first magnetic field.

In another representative embodiment, a duplexer interfacing a receiver and a transmitter with a common antenna includes first and second filters and a first shielding bondwire. The first filter is connected between the antenna and the transmitter, and includes a first filter die mounted on a top surface of a printed circuit board and a first bondwire connecting the first filter die to the printed circuit board. The first bondwire and a first conductor of the printed circuit board form a portion of a first virtual loop having a first virtual area, where the first bondwire is configured to generate a first magnetic field when first current passes through the first bondwire. The second filter is connected between the antenna and the receiver, and includes a second filter die mounted on the top surface of the printed circuit board and a second bondwire connecting the first filter die to the printed circuit board. The second bondwire and a second conductor of the printed circuit board form a portion of a second virtual loop having a second virtual area, where the second bondwire is configured to generate a second magnetic field when second current passes through the second bondwire. The first shielding bondwire includes first and second ends connected to a third conductor of the printed circuit board to form a closed electrical first shielding loop having a corresponding shielding area, where at least one of the first magnetic field and the second magnetic field induces shielding current passing through the first shielding loop, which generates a first compensating magnetic field that compensates for at least a portion of the at least one of the first magnetic field and the second magnetic field, respectively, reducing magnetic interference between the first and second filters.

In yet another representative embodiment, a magnetic shield is provided for increasing isolation and reducing cross-talk between a transmit filter and a receive filter of a duplexer, mounted on a printed circuit board. The magnetic shield includes a shielding bondwire shorted to a conductive layer of the printed circuit board between the transmit filter and the receive filter. The first shielding bondwire forms a closed electrical shielding loop, where a bondwire magnetic field generated by a bondwire connected to one of the transmit filter and the receive filter induces current in the shielding bondwire, which generates a compensating magnetic field that attenuates the bondwire magnetic field.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a block diagram illustrating a duplexer with a bondwire magnetic shield, according to a representative embodiment.

FIG. 2 is a cross-sectional diagram illustrating a shielding bondwire connected to a printed circuit board, along line a-a′ of FIG. 1, according to a representative embodiment.

FIG. 3 is a cross-sectional diagram illustrating a bondwire connecting a transmit filter die and a printed circuit board, along line b-b′ of FIG. 1, according to a representative embodiment.

FIG. 4A is a cross-sectional diagram illustrating stacked shielding bondwires on a printed circuit board, according to a representative embodiment.

FIG. 4B is a cross-sectional diagram illustrating parallel shielding bondwires on a printed circuit board, according to a representative embodiment.

FIG. 4C is a top perspective view illustrating cascaded shielding bondwires on a printed circuit board, according to a representative embodiment.

FIGS. 5A and 5B are top perspective views illustrating duplexers with bondwire magnetic shields, according to representative embodiments.

FIG. 6 is a curve plotting magnitude S-parameter measurements of isolation in dB between transmitter and receiver ports with and without shielding bondwires, as shown in FIGS. 5A and 5B, according to representative embodiments.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Generally, it is understood that the drawings and the various elements depicted therein are not drawn to scale. Further, relative terms, such as “above,” “below,” “top,” “bottom,” “upper” and “lower” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element.

In addition, it is understood that when an element is referred to as “connected” or “coupled” to another element, it can be directly connected or coupled to the other element or intervening elements may be present. Similarly, when an element is referred to as “electrically connected” or “electrically coupled” to another element, or in “electrical contact with” another element, it can be directly connected or coupled to the other element or intervening elements may be present, so long as electrical connection between the elements is made. In contrast, when an element is referred to as being “directly connected” or “directly coupled” to another element, there are no intervening elements present.

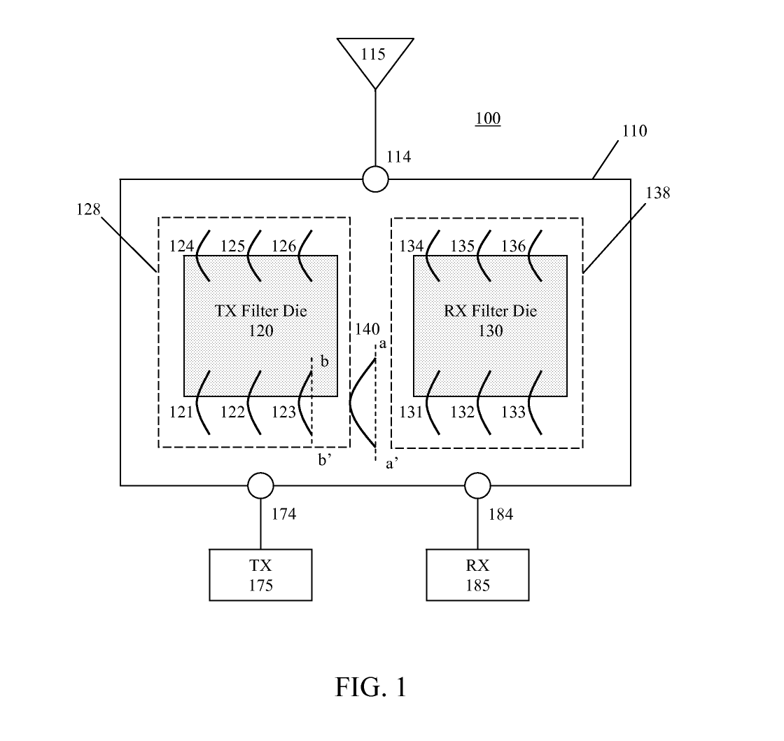

FIG. 1 is a block diagram illustrating a duplexer with a bondwire magnetic shield, according to a representative embodiment.

Referring to FIG. 1, representative duplexer 100 is formed on printed circuit board 110, and interfaces transmitter (TX) 175 and receiver (RX) 185 with a common antenna 115, for sending and receiving wireless communications signals, respectively. The wireless communications signals may be RF signals, for example, complying with various communication standards, such as universal mobile telecommunications system (UMTS), Long Term Evolution (LTE), and personal communications services (PCS). The printed circuit board 110 includes a substrate formed from any material, which can be used to mount filter dies, such as transmit filter die 120 and receive filter die 130. The transmit and receive filter dies 120 and 130 may be based on semiconductor substrates, for example, formed of materials such as silicon (Si), gallium arsenide (GaAs), or indium phosphide (InP).

In the depicted representative embodiment, the duplexer 100 includes the transmit filter die 120, which is mounted to the top surface of the printed circuit board 110. Transmit filter 128 includes the transmit filter die 120 and transmit bondwires 121-128. The transmit filter 128 is connected between the transmitter 175 through transmitter port 174 and antenna 115 through antenna port 114. The duplexer 100 further includes the receive filter die 130, which is also mounted to the top surface of the printed circuit board 110, next to the transmit filter die 120. Receive filter 138 includes the receive filter die 130 and receive bondwires 131-138. The receive filter 138 is connected between the receiver 185 through receiver port 184 and the antenna 115 through the antenna port 114. The antenna port 114, the transmitter port 174 and the receiver port 184 may correspond to connectors, pads or other terminals on the printed circuit board 110, respectively.

According to various embodiments, the transmit filter die 120 and the receive filter die 130 may be film bulk acoustic resonator (FBAR) filters or bulk acoustic wave (BAW) resonator filters, which include multiple FBAR or BAW resonators, respectively, an example of which is discussed below with reference to FIG. 7. Alternatively, each of the transmit filter and the receive filter may be any other type of filter, such as a coupled resonator filter (CRF) or a surface acoustic wave (SAW) filter, for example, without departing from the scope of the present teachings. The transmit filter 128 and the receive filter 138 may also include various architectures, such as ladder filters or lattice filters, for example.

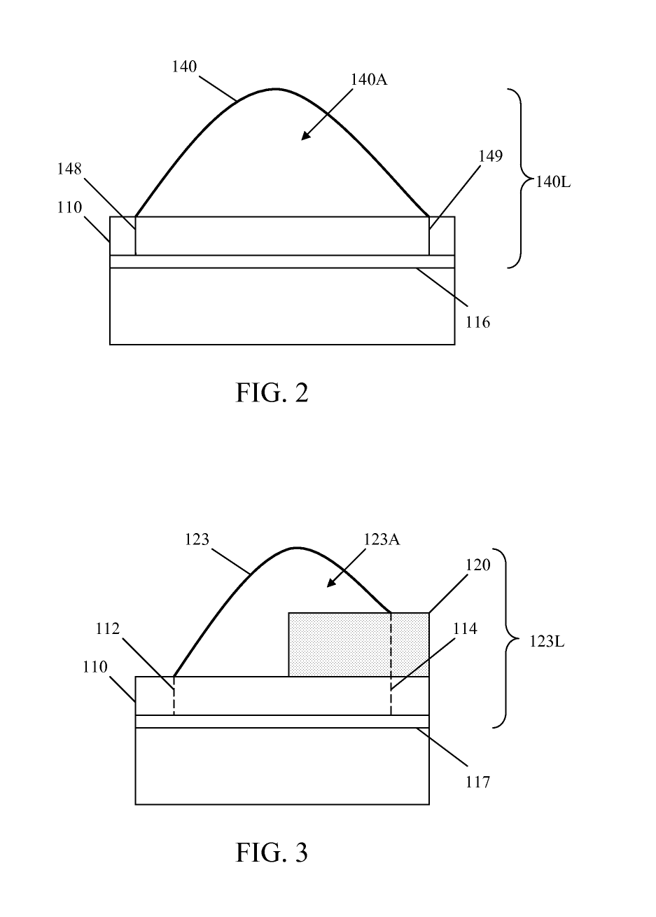

The transmit filter 128 and the receive filter 138 are separated by a bondwire magnetic shield, which includes shielding bondwire 140 located between the transmit filter die 120 and the receive filter die 130 on top surface of the printed circuit board 110. The shielding bondwire 140 is shorted, in that both of the first and second ends of the shielding bondwire 140 are electrically connected via one or more conductors to form a closed electrical shielding loop. The closed electrical shielding loop of the shielding bondwire 140 defines a corresponding shielding area, discussed below with reference to FIG. 2. The one or more conductors may include a conductive coating (or laminate) or a conductive trace on the top surface of the printed circuit board 110, or a conductive layer or conductive trace buried in the substrate of the printed circuit board 110 (e.g., conductive layer 116 shown in FIG. 2), or various combinations thereof. The shielding bondwire 140 is configured to reduce magnetic coupling (e.g., magnetic crosstalk) and to improve isolation between the transmit filter 128 and the receive filter 138.

The transmit filter die 120 is electrically connected to circuitry of the printed circuit board 110 by illustrative transmit bondwires 121-126, and the receive filter die 130 is electrically connected to circuitry of the printed circuit board 110 by illustrative receive bondwires 131-136. For example, the input of the transmit filter die 120 may be connected to the transmitter port 174 for receiving transmit signals from the transmitter 175 through transmit bondwire 123, and the output of the receive filter die 130 may be connected to the receiver port 184 for sending filtered receive signals to the receiver 185 through receive bondwire 131. Similarly, the output of the transmit filter die 120 may be connected to the antenna port 114 for transmitting filtered transmit signals from the antenna 115 through transmit bondwire 126, and the input of the receive filter die 130 may be connected to the antenna port 114 for receiving receive signals from the antenna 115 through receive bondwire 134, for example. In addition, inductances formed by the transmit bondwires 121-126 and the receive bondwires 131-136 may be used to achieve desired filtering functions.

Of course, the number, location and functionality of the transmit and receive bondwires may vary to provide unique benefits for any particular situation or to meet application specific design requirements of various implementations, as would be apparent to one skilled in the art. The transmit bondwires 121-126, the receive bond wires 131-136 and the shielding bondwire 140 may be formed from any conductive material compatible with semiconductor processes, such as gold (Au), aluminum (Al), copper (Cu), or combinations thereof.

As discussed above, the transmit filter 128 and the receive filter 138 have corresponding passbands, which differ from one another. It may be assumed for purposes of discussion that the receive filter 138 has a higher passband than the transmit filter 128, although the opposite may be true in alternative implementations. The stopband of the transmit filter 128 is in the passband of the receive filter 138, and likewise, the stopband of the receive filter 138 is in the passband of the transmit filter 128. With respect to a particular frequency, the one of the transmit filter 128 and the receive filter 138 that is in its passband is the active filter, and the other one of the transmit filter 128 and the receive filter 138 that is in its stopband is the passive filter. Accordingly, when a signal at the particular frequency is supplied to the active filter, as defined by that frequency, the magnetic field of the active filter will tend to induce a voltage signal in one or more bondwires of the passive filter, and create magnetic crosstalk.

To prevent the crosstalk, the shielding bondwire 140 is placed between the bondwires 121-123 and 131-133, in the depicted example. FIG. 2 is a cross-sectional diagram illustrating the shielding bondwire 140 connected to the printed circuit board 110, along line a-a′ of FIG. 1, according to a representative embodiment.

Referring to FIG. 2, the shielding bondwire 140 forms a closed electrical shielding loop 140L, which surrounds and defines corresponding shielding area 140A. In particular, the shielding bondwire 140 is connected at first and second ends to conductor 116, which may be buried in substrate 111 of the printed circuit board 110, via connectors 148 and 149, respectively. The conductor 116 may be a conductive trace or a conductive layer (e.g., a ground layer), for example, and is not necessarily in the plane of the cross-section and/or is not necessarily parallel to the shielding bondwire 140, as shown in FIG. 2. The shielding area 140A is the area within the perimeter or rim of the shielding loop 140L, formed by the shielding bondwire 140, the conductor 116, and the connectors 148 and 149. In alternative configurations, the conductor 116 may be a conductive coating or conductive trace on the top surface of the printed circuit board 110 to close the electrical shielding loop 140L, in which case there would be no need for the connectors 148 and 149. In various configurations, a via wall (not shown) may be placed between the conductor 116 , which may be on the top surface, and any other conductor or conductive layer in the substrate, including a conductive layer on the opposite surface (bottom surface) to the top surface, in order to provide additional shielding by compensating for magnetic field within the printed circuit board 110. Further, the printed circuit board 110 may have multiple conductive layers (not shown), including the conductor 116, in which case the shielding loop 140L may include portions of the multiple conductive layers interconnected by vias.

Generally, a dynamic (changing with time) magnetic field generated by current passing through one or more bondwires of the active filter (driving magnetic field) induces a current in the shielding loop 140L of the shielding bondwire 140 (“shielding current”) when the shielding loop 140L is subject to the generated magnetic field. The shielding current, in turn, generates a compensating magnetic field that attenuates the active filter magnetic field at least in the vicinity of the shielding loop, reducing the magnetic crosstalk. In other words, the compensating magnetic field superimposes on the driving magnetic field to produce a zero or negligible effective magnetic field at least in the vicinity of the shielding loop. However, the bondwires of the active filter may not form closed electrical loops. A virtual loop must therefore be considered for each bondwire, as discussed below with reference to FIG. 3.

FIG. 3 is a cross-sectional diagram illustrating transmit bondwire 123 connected to the printed circuit board 110, along line b-b′ of FIG. 1, according to a representative embodiment. The transmit bondwire123 is shown only for purposes of illustration, and thus it is understood that the discussion applies to any of the transmit bondwires 121-126 and the receive bondwires 131-136.

Referring to FIG. 3, the transmit bondwire 123 forms a virtual loop 123L, which surrounds and defines corresponding virtual area 123A. In particular, first and second ends of the transmit bondwire 123 may not be directly connected to the conductor 117, which may be buried in substrate 111 of the printed circuit board 110. The conductor 117 may be a conductive trace or a conductive layer (e.g., a ground layer), for example, and is not necessarily in the plane of the cross-section and/or is not necessarily parallel to the transmit bondwire 123, as shown in FIG. 3. Further, the conductor 117 may be the same as or different from the conductor 116, discussed above. For example, the first end of the transmit bondwire 123 may be connected to circuitry on the printed circuit board 110, and the second end of the transmit bondwire 123 may be connected to circuitry of the transmit filter die 120, and thus is not directly connected to the conductor 117. Accordingly, it may be assumed that the first and second ends of the transmit bondwire 123 are virtually connected to the conductor 116 via first and second virtual paths 112 and 114, respectively, indicated by dashed lines, to form the closed virtual loop 123L. In the depicted configuration, the first virtual path 112 passes through the printed circuit board 110 at the connection point of the transmit bondwire 123, and extends substantially vertically to the conductor 117. The second virtual path 114 similarly passes through the transmit filter die at the connection point of the transmit bondwire 123, and extends substantially vertically through the printed circuit board 110 to the conductor 117.

The virtual area 123A is therefore defined as the area within the perimeter or rim of the virtual loop 123L, formed by the transmit bondwire 123, the conductor 117, the first virtual path 112 and the second virtual path 114. Generally, the virtual loop 123L is closed virtually by the conductor 117 (e.g., the ground plane), although the conductor 117 may not be directly connected to the transmit bondwire 123, due to mirror current induced in the conductor 117. That is, the conductor 117 is typically the uppermost conductor or conductive layer that carries the mirror current of the current passing through the transmit bondwire 123, which may be the bondwire current itself.

Alternatively, the first end of the bondwire 123 may be directly connected to the conductor 117, for example, this could be the case when the bondwire 123 is a ground bondwire. In this case, the first virtual path 112 would be replaced by a conductive connector (not shown in FIG. 3), and the closed virtual loop 123L is formed by the transmit bondwire 123, the conductor 117, the second virtual path 114 and the conductive connecter replacing the first virtual path 112. Otherwise, the virtual area 123A is defined as the area within the perimeter or rim of the virtual loop 123L as discussed above.

Referring to FIGS. 1-3, the shielding loop 140L (and thus the shielding bondwire 140) is located where magnetic crosstalk occurs, that is, in the depicted example, where the magnetic field generated by illustrative transmit bondwire 123 induces a voltage signal in the receive filter die 130 and/or one or more of the receive bondwires 131-133, or vice versa. Unlike a shield consisting of a housing or a wall of conductive material, for example, the shielding loop 140L only provides compensation for an area integral of the magnetic field corresponding to the virtual area 140A, as discussed below. Therefore, the shielding loop 140L is related to the virtual loop(s) of the active filter bondwires in which magnetic fields are generated (e.g., virtual loop 123L of transmit bondwire 123, as well as virtual loops corresponding to transmit bondwires 121-122) and the virtual loop(s) of the passive filter bondwires (e.g., virtual loops corresponding to receive bondwires 131-133).

For purposes of simplifying explanation, it may be assumed that the duplexer 100 includes one active filter bondwire (e.g., transmit bondwire 123) and one passive filter bondwire (e.g., receive bondwire 131), although it is understood that various implementations may include one or more additional active and/or passive filter bondwires with corresponding virtual areas, without departing from the scope of the present teachings. In various embodiments, the shielding bondwire loop 140L is formed such that it circumscribes the same area as the virtual area of the related active filter bondwire (e.g., virtual area 123A corresponding to transmit bondwire 123 in the present example) and/or the related passive filter bondwire. For example, the virtual area of the active filter bondwire may be projected across the printed circuit board 110 onto the virtual area of the passive bondwire, defining a virtual tunnel connecting the active and passive filter bondwires. Alternatively, the virtual area of the passive filter bondwire may be projected across the printed circuit board 110 onto the virtual area of the active bondwire to define the virtual tunnel. For example, the shielding bondwire loop 140L may be configured to substantially circumscribe the outer perimeter of at least a portion of the virtual tunnel between the active and passive filter bondwires, where the shielding bondwire loop 140L is arranged generally perpendicular to a longitudinal axis of the virtual tunnel.

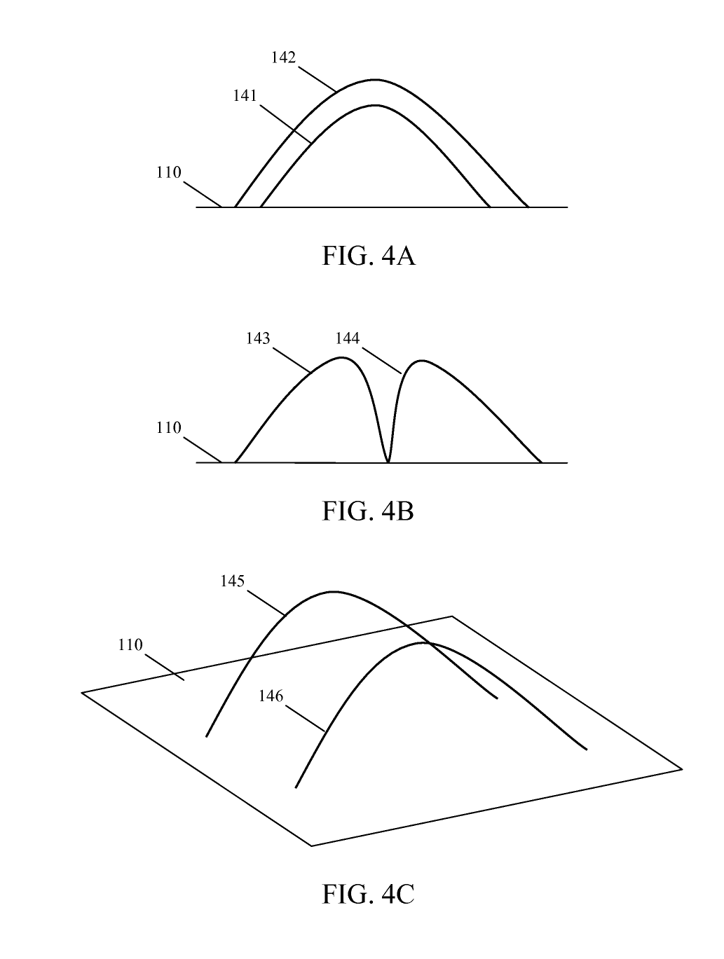

In an embodiment, the shielding loop 140L formed, in part, by the shielding bondwire 140, is the same size or larger than the virtual loop (e.g., virtual loop 123L) formed, in part, by the active filter bondwire that generates the magnetic field. This is because portions of the magnetic field outside of the shielding loop 140L will not be attenuated and thus may still cause magnetic crosstalk. However, in various configurations, the shielding loop 140L may be smaller than the virtual loop. For example, a smaller shielding loop 140L may sufficiently attenuate the magnetic field for a particular application, such that further attenuation is superfluous. Also, when the magnetic shield consists of multiple shielding loops, as discussed below with reference to FIGS. 4A-4C, one or more of the multiple shielding loops may be smaller than the virtual loop. When multiple active filter bondwires are in place, the size of the shielding bondwire loop(s) is determined to compensate for the collective magnetic field provided by the corresponding magnetic fields generated by the multiple active filter bondwires.

The characteristics of the magnetic field generated by the active filter bondwire(s) may also be a consideration. For example, when the magnetic field is about the same direction and magnitude, then the shielding loop 140L may be larger, yet still provide adequate compensation. However, one should avoid including areas in the shielding loop 140L where the direction of the magnetic field is substantially “disorientated” or even in opposite direction, since this would reduce the compensation effect due to the integral nature of the compensation.

In alternative embodiments, the shielding bondwire 140 may be replaced by multiple shielding bondwires in various configurations, without departing from the scope of the present teachings. FIGS. 4A-4C depict examples in which multiple shielding bondwires are located on the printed circuit board 110 in order to provide shielding from magnetic crosstalk, according to various embodiments.

More particularly, FIG. 4A is a cross-sectional diagram illustrating stacked shielding bondwires 141 and 142 on the printed circuit board 110, according to a representative embodiment. First shielding bondwire 141 has first and second ends connected to a conductor on or in the printed circuit board 110, forming a first closed electrical shielding loop that defines a corresponding first shielding area, as discussed above with reference to shielding bondwire 140 in FIG. 2. Likewise, second shielding bondwire 142 has first and second ends connected to a conductor on or in the printed circuit board 110, forming a second closed electrical shielding loop that defines a corresponding second shielding area. The second shielding bondwire 142 is stacked on the first shielding bondwire 141, such that the second shielding area entirely contains within the first shielding area. In various configurations, the first and second shielding bondwires 141 and 142 may connected to the same or different conductors on or in the printed circuit board 110.

In the depicted configuration, the magnetic field generated by the active filter bondwire(s) (e.g., representative transmit bondwire 123 shown in FIG. 2) simultaneously induces a first current in the first shielding bondwire 141 and a second current in the second shielding bondwire 142, which in turn generate a first compensating magnetic field and a second compensating magnetic field, respectively. The first and second compensating magnetic fields influence one another, such that the induced first and second currents and corresponding effective magnetic fields depend on the total arrangement. Stacking the first and second shielding bondwires 141 and 142 is particularly useful when there are multiple active filter bondwires having corresponding virtual loops with different sizes, in which case the first and second shielding areas may be sized for optimal attenuation of the magnetic fields generated by the respective virtual loops. Also, stacking the first and second shielding bondwires 141 and 142 as shown in FIG. 4A is generally useful when the magnetic fields are not homogeneous, e.g., across the area of the outer shielding loop (created by the second shielding bondwire 142 in the depicted illustrative configuration), where a “homogeneous” magnetic field in this context would be a magnetic field that is perfectly compensated for using one shielding bondwire. By using smaller shielding loops (created by the first shielding bondwire 141 in the depicted illustrative configuration), non-homogeneous magnetic fields are more effectively attenuated or cancelled. Generally, the effectiveness improves with additional stacked bondwires, considering that ultimately the stacked bondwires would form a shielding wall, which of would provide the most effective shielding.

FIG. 4B is a cross-sectional diagram illustrating parallel shielding bondwires 143 and 144 on the printed circuit board 110, forming parallel shielding loops, according to a representative embodiment. First shielding bondwire 143 has first and second ends connected to a conductor on or in the printed circuit board 110, forming a first closed electrical shielding loop that defines a corresponding first shielding area, as discussed above with reference to shielding bondwire 140 in FIG. 2. Likewise, second shielding bondwire 144 has first and second ends connected to a conductor on or in the printed circuit board 110, forming a second closed electrical shielding loop that defines a corresponding second shielding area. The first and second shielding bondwires 143 and 144 are in parallel with one another, in that they are arranged end-to-end on the printed circuit board 110, such that the first shielding area is adjacent the second shielding area. In various configurations, the first and second shielding bondwires 143 and 144 may connected to the same or different conductors on or in the printed circuit board 110.

In the depicted configuration, the magnetic field generated by the active filter bondwire(s) (e.g., representative transmit bondwire 123 shown in FIG. 2) simultaneously induces a first current in the first shielding bondwire 143 and a second current in the parallel second shielding bondwire 144, which in turn generate a first compensating magnetic field and a second compensating magnetic field, respectively. The first and second compensating magnetic fields influence one another, such that the induced first and second currents and corresponding effective magnetic fields depend on the total arrangement. Because the first and second shielding bondwires 143 and 144 are arranged beside one another, they are affected by different portions of the magnetic field generated by the active filter bondwire(s). Arranging the first and second shielding bondwires 143 and 144 in parallel is generally useful when the magnetic field is not homogeneous, as discussed above, resulting in better compensation. By using additional parallel shielding loops, non-homogeneous magnetic fields are more effectively attenuated or cancelled. This may be particularly useful, for example, when the effective magnetic fields of multiple active filter bondwires change significantly with frequency across a passband due to different phases in the bondwires. For example, the effective magnetic fields of multiple active filter bondwires may change when the active filter bondwires are arranged beside one another (unlike the configuration shown in FIG. 1).

FIG. 4C is a top perspective view illustrating cascaded shielding bondwires 145 and 146 on the printed circuit board 110, according to a representative embodiment. First shielding bondwire 145 has first and second ends connected to a conductor on or in the printed circuit board 110, forming a first closed electrical shielding loop that defines a corresponding first shielding area, as discussed above with reference to shielding bondwire 140 in FIG. 2. Likewise, second shielding bondwire 146 has first and second ends connected to a conductor on or in the printed circuit board 110, forming a second closed electrical shielding loop that defines a corresponding second shielding area. The first and second shielding bondwires 145 and 146 are about the same size, and are cascaded across the top surface of the printed circuit board 110, such that the first shielding area and the second shielding area are substantially aligned with one another in a direction from the active filter to the passive filter. In various configurations, the first and second shielding bondwires 145 and 146 may connected to the same or different conductors on or in the printed circuit board 110.

In the depicted configuration, the magnetic field generated by the active filter bondwire(s) (e.g., representative transmit bondwire 123 shown in FIG. 2) is attenuated in consecutive stages. This means that a portion of the total attenuation occurs in succession at each cascaded shielding bondwire. For example, the magnetic field generated by the active filter bondwire(s) induces a first current in the first shielding bondwire 145, which in turn generates a first compensating magnetic field. The first compensating magnetic field generated by the first shielding bondwire 145, along with any remaining driving magnetic field, induce a second current (smaller than the first current) in the second shielding bondwire 146, which in turn generates a second compensating magnetic field to compensate further for the driving magnetic field. The first and second compensating magnetic fields influence one another, such that the induced first and second currents and corresponding effective magnetic fields depend on the total arrangement. Accordingly, the first and second shielding bondwires 145 and 146 attenuate the magnetic field generated by the active filter bondwire(s) in a stepwise fashion. Again, the arrangement of the first and second shielding bondwires is also useful when the magnetic field is not homogeneous, as discussed above.

Notably, an additional advantage of one or more of the examples of multiple shielding bondwires located on the printed circuit board 110, shown in FIGS. 4A-4C, is that they may comply with more strict technical limitations regarding placement of the shielding bondwires. For example, design rules may require the shielding bondwires to be placed in non-optimal locations, but overall magnetic field compensation may still be improved using the multiple shielding bondwires.

As a theoretical basis, the various embodiments are in accordance with the third Maxwell equation (“Faraday's law of induction”). Generally, a magnetic field cannot penetrate a sheet of perfect conducting material (other than a constant magnetic field, which was present when the sheet was created). This inability to penetrate may be viewed as a sequence of instantaneously acting events. The magnetic field initially penetrating the perfect conducting material induces an electrical field in the sheet. Since the material is perfect conducting material, the electrical field would drive an infinite current. However, because another magnetic field associated with the induced current compensates for the initially penetrating magnetic field, the induced current is actually finite. In fact, the associated current distribution is limited, such that it exactly compensates for the initial/external magnetic field in the sheet.

In RF wireless communications, the same is approximately true for good conductors with finite conductivity, since the voltage drop due to resistance is small with respect to the induced voltage due to the high frequency. Therefore, from the third Maxwell equation, it follows:

$${∮}_{δ A} E \cdot d s + \frac{d}{d t} ( \int {\int }_{A} B \cdot d A ) = 0$$

Thus, the same mechanism as described for a perfect conducting sheet is applicable for an area defined by a closed current path, such as the closed electrical shielding loop 140L shown in FIG. 2. The third Maxwell equation in principal states that an area A of a penetrating and changing magnetic field will induce an electrical field E along the rim 6A of the area A. If the perimeter or rim surrounding the area A is perfect conducting wire, the magnetic field would induce an infinite current, except that the induced current would be limited by the fact that it generates a compensating magnetic field that compensates for the original driving magnetic field. Therefore, the current induced in the shielding loop 140L will be set such that it compensates for the driving effect. In other words, the area integral of the (combined) effective magnetic field over the considered area will be zeroed. Notably, in a sheet of perfect conducting material, the induced current distribution would be such that the driving magnetic field would be compensated for at each point in the sheet, while in an area of a loop of wire (e.g., shielding area 140A), the driving magnetic field is compensated for only on the integral of the driving magnetic field over the shielding area due to the limited current distribution. That is, if the “external” magnetic field is similarly distributed as a magnetic field that can be created by the shielding loop (having a distribution defined by the form of the shielding loop), then perfect compensation can be achieved (assuming a perfect conducting loop).

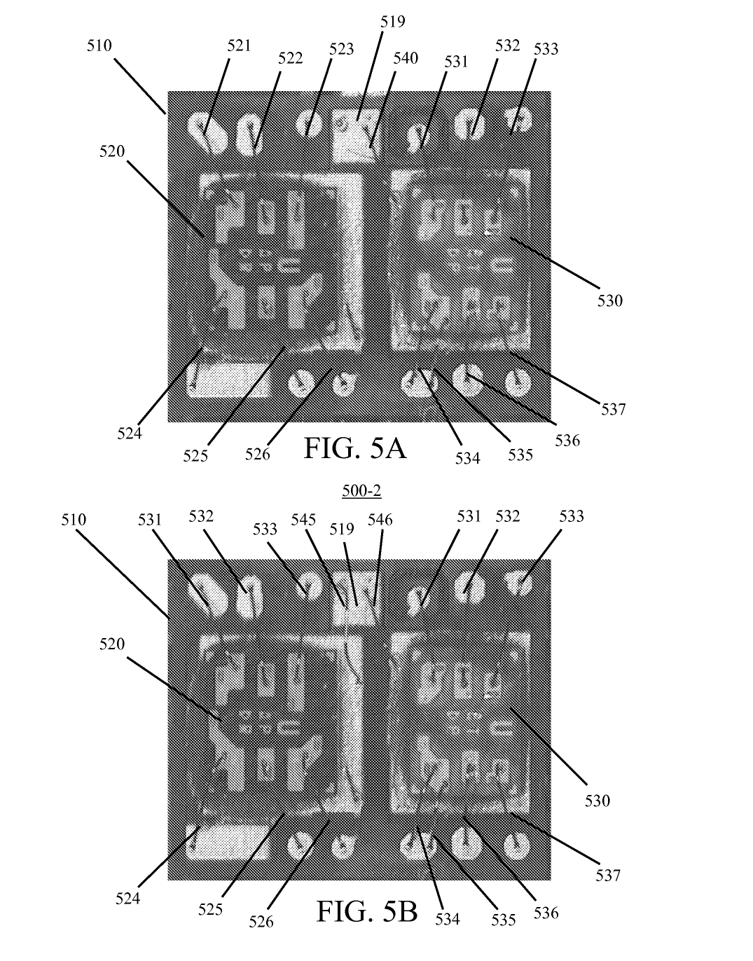

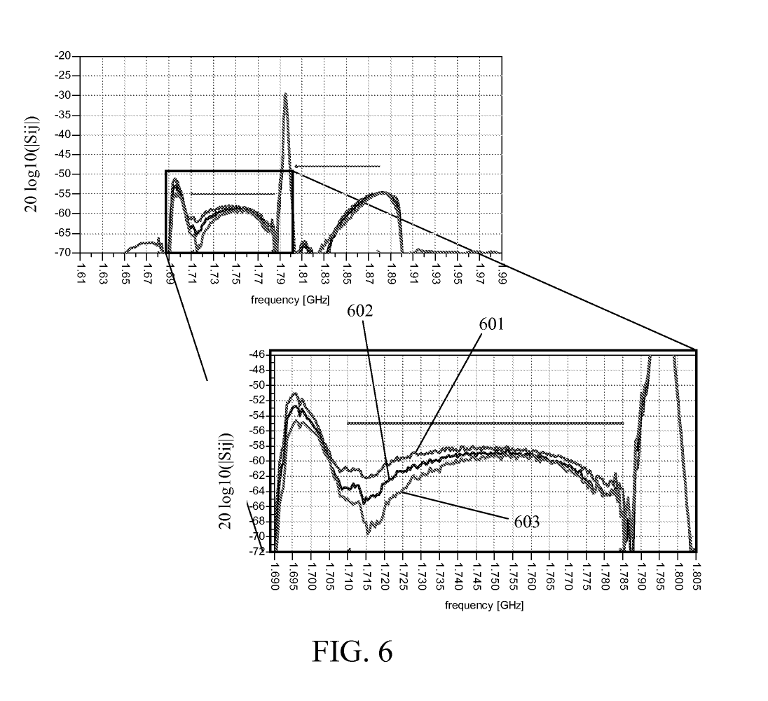

FIGS. 5A and 5B are top plan views illustrating duplexers with bondwire magnetic shields, respectively including one and two bondwires, according to representative embodiments. FIG. 6 is a graph of curves showing S-parameter measurements t of the duplexer without shielding bondwires and with shielding bondwires, as shown in FIGS. 5A and 5B, according to representative embodiments. In particular, the curves in FIG. 6 show the transmission (isolation) S-parameter from the transmitter port to the receiver port.

Referring to FIG. 5A, representative duplexer 500-1 is formed on printed circuit board 510, and interfaces a transmitter and a receiver with a common antenna (not shown), for sending and receiving wireless communications signals, respectively. The duplexer 500-1 includes transmit filter die 520 and receive filter die 530, which are mounted to the top surface of the printed circuit board 510. The transmit filter die 520 and the receive filter die 530, together with transmit bondwires 521-526 and receive bondwires 531-537, form a transmit filter and a receive filter, respectively, as discussed above with regard to transmit filter 128 and receive filter 138 in FIG. 1. The transmit filter die 520 and the receive filter die 530 are separated by a bondwire magnetic shield, which includes single shielding bondwire 540, as discussed above with reference to shielding bondwire 140 shown in FIG. 1. The shielding bondwire 540 is connected to a conductive layer 519 exposed on the top surface of the printed circuit board 510 (other portions of which are covered by an insulating material, such as an oxide layer), to form a corresponding closed electrical shielding loop.

For purposes of explanation, it may be assumed that the transmit filter is the active filter and the receive filter is the passive filter, such that current flowing through one or more of the transmit bondwires 521-523 generates a collective magnetic field, which would induce voltage signals in one or more of the receive bondwires 531-533, as discussed above. However, in the depicted configuration, the magnetic field induces a shielding current in the shielding bondwire 540, which in turn generates a compensating magnetic field that compensates for the magnetic field generated by the transmit bondwires 521-523. The shielding bondwire 540 thus reduces magnetic coupling (e.g., magnetic crosstalk) and improves isolation between the transmit and receive filters, compared to the same duplexer with no shielding bondwires, as indicated by curves 601 and 602 in FIG. 6.

Similarly, referring to FIG. 5B, representative duplexer 500-2 is formed on the printed circuit board 510, and interfaces a transmitter and a receiver with a common antenna (not shown), for sending and receiving wireless communications signals, respectively. The duplexer 500-2 includes transmit filter die 520 and receive filter die 530, which are mounted to the top surface of the printed circuit board 510, as discussed above with reference to FIG. 5A. However, in duplexer 500-2, the bondwire magnetic shield separating the transmit filter die 520 and the receive filter die 530 includes first shielding bondwire 545 and second shielding bondwire 546, which are cascaded, as discussed above with reference to first shielding bondwire 145 and second shielding bondwire 146 shown in FIG. 4C. Each of the first and second shielding bondwires 545 and 546 are connected to a conductive layer 519 on the top surface of the printed circuit board 110, to form corresponding closed electrical shielding loops.

Again, for purposes of explanation, it may be assumed that the transmit filter is the active filter and the receive filter is the passive filter, such that current flowing through one or more of the transmit bondwires 521-523 generates a collective magnetic field, which would induce voltage signals in one or more of the receive bondwires 531-533, as discussed above. However, in the depicted configuration, the magnetic field induces first and second shielding currents in the first and second shielding bondwires 545 and 546, respectively, which in turn generate first and second compensating magnetic fields, which compensate for the magnetic field generated by the transmit bondwires 521-523. The first and second shielding bondwires 545 and 546 thus reduce magnetic coupling (e.g., magnetic crosstalk) and improve isolation between the transmit and receive filters, compared to the same duplexer with no shielding bondwires, as indicated by curves 601 and 603 in FIG. 6, and as compared to duplexer 500-1 with a single shielding bondwire 540, as indicated by curves 602 and 603 in FIG. 6.

FIG. 6 is a graph of curves showing the magnitude of the measured S-parameter, which is describing the isolation/transmission between transmitter and receiver ports with and without shielding bondwires, as shown in FIGS. 5A and 5B, according to representative embodiments. The S-parameter measurements are plotted as a function of frequency in GHz (horizontal axis) and magnitude in dB (vertical axis). Generally, FIG. 6 shows the magnitude of the S-parameter (Sᵢⱼ) which is one matrix element of the three port 5-matrix as formed by the duplexer due to its three electrical terminals (transmitter port, receiver port, antenna port). In the S-parameter matrix element Sᵢⱼ, i relates to the receiver port and j to the transmitter port (or vice versa, since it is a reciprocal network), such that Sᵢⱼ describes the transmission from the transmitter to the receiver.

The plots in FIG. 6 show examples of attenuation of RF power from one port to another with respect to the related reference impedance. In particular, curve 601 shows the signal strength of a signal measured in the passband of the transmit filter (e.g., the active filter in the present example), indicating isolation or signal attenuation, with no magnetic shield separating the active and passive filters. Curve 602 shows the signal strength of a signal measured in the passband of the transmit filter with single shielding bondwire 540, as shown in FIG. 5A, indicating isolation or signal attenuation. As compared to curve 601, curve 602 shows an increase in isolation by up to about 2 dB, for example, due to compensation of the magnetic field. Curve 603 shows the signal strength of a signal measured in the passband of the transmit filter with cascaded first and second shielding bondwires 545 and 546, as shown in FIG. 5B. As compared to curve 601, curve 603 shows an increase in isolation by up to about 5 dB, for example.

As mentioned above, the transmit filter 128 and the receive filter 138 of the duplexer 100, shown in FIG. 1, may be any of a variety of filters, including FBAR, BAW resonator filters, as well as CRFs. Examples of duplexers having FBAR and BAW resonator transmit and receive filters are discussed, for example, by BRADLEY et al., in U.S. Patent Application Pub. No. 2011/0018653, published Jan. 27, 2011, and by FRITZ et al., in U.S. Patent Application Pub. No. 2011/0128092, published Jun. 2, 2011, which are hereby incorporated by reference in their entireties.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A duplexer, comprising:
a first filter comprising a first bondwire connecting the first filter to a printed circuit board, the first bondwire forming a portion of a first virtual loop having a first virtual area, wherein first current passing through the first bondwire generates a first magnetic field;
a second filter comprising a second bondwire connecting the second filter to the printed circuit, the second bondwire forming a portion of a second virtual loop having a second virtual area; and
a first shielding bondwire comprising first and second ends connected to a conductor of the printed circuit board to form a closed electrical first shielding loop having a corresponding first shielding area, wherein the first magnetic field induces shielding current in the first shielding loop, which generates a first compensating magnetic field that attenuates the first magnetic field.

2. The duplexer of claim 1, wherein the first shielding loop substantially circumscribes a portion of a virtual tunnel projected from the first virtual loop to the second virtual loop.

3. The duplexer of claim 1, wherein a direction of a normal vector of the first shielding area of the first shielding loop is substantially parallel to an average direction of the first magnetic field in the area of the loop.

4. The duplexer of claim 1, wherein the conductor to which the first shielding bondwire is connected comprises one of a conductive layer or a conductive trace buried in the printed circuit board.

5. The duplexer of claim 1, wherein the conductor to which the first shielding bondwire is connected comprises a conductive portion of a surface of the printed circuit board.

6. The duplexer of claim 1, wherein the first filter has a corresponding passband and the second filter has a corresponding stopband in a frequency range of the passband of the first filter.

7. The duplexer of claim 1, further comprising:
a second shielding bondwire comprising first and second ends connected to a conductor of the printed circuit board to form a closed electrical second shielding loop having a corresponding second shielding area, wherein the first compensating magnetic field and the first magnetic field induce shielding current passing through the second shielding loop, which generates a second compensating magnetic field that further attenuates the first magnetic field.

8. The duplexer of claim 7, wherein the second shielding bondwire is stacked on the first shielding bondwire.

9. The duplexer of claim 7, wherein the second shielding bondwire is connected in parallel with the first shielding bondwire, and wherein the first magnetic field simultaneously induces shielding current in the first shielding loop and the second shielding loop.

10. The duplexer of claim 7, wherein the second shielding bondwire and the first shielding bondwire have a cascading arrangement, and
wherein the second shielding bondwire and the first shielding bondwire attenuate the first magnetic field in consecutive stages.

11. The duplexer of claim 1, wherein the first shielding area is substantially the same size as the first virtual area of the first virtual loop.

12. The duplexer of claim 1, wherein the first shielding area is larger than the first virtual area of the first virtual loop.

13. The duplexer of claim 1, wherein the first shielding area is smaller than the first virtual area of the first virtual loop.

14. A duplexer interfacing a receiver and a transmitter with a common antenna, the duplexer comprising:
a first filter connected between the antenna and the transmitter, the first filter comprising a first filter die mounted on a top surface of a printed circuit board and a first bondwire connecting the first filter die to the printed circuit board, the first bondwire and a first conductor of the printed circuit board forming a portion of a first virtual loop having a first virtual area, wherein the first bondwire is configured to generate a first magnetic field when first current passes through the first bondwire;
a second filter connected between the antenna and the receiver, the second filter comprising a second filter die mounted on the top surface of the printed circuit board and a second bondwire connecting the second filter die to the printed circuit board, the second bondwire and a second conductor of the printed circuit board forming a portion of a second virtual loop having a second virtual area, wherein the second bondwire is configured to generate a second magnetic field when second current passes through the second bondwire; and
a first shielding bondwire comprising first and second ends connected to a third conductor of the printed circuit board to form a closed electrical first shielding loop having a corresponding shielding area, wherein at least one of the first magnetic field and the second magnetic field induces shielding current passing through the first shielding loop, which generates a first compensating magnetic field that compensates for at least a portion of the at least one of the first magnetic field and the second magnetic field, respectively, reducing magnetic interference between the first and second filters.

15. The duplexer of claim 14, wherein the first shielding loop substantially circumscribes a portion of a first virtual tunnel projected between the first virtual loop and the second virtual loop.

16. The duplexer of claim 14, further comprising:
a second shielding bondwire comprising first and second ends connected to a fourth conductor of the printed circuit board to form a closed electrical second shielding loop having a corresponding shielding area, wherein at least one of the first magnetic field and the second magnetic field induces shielding current passing through the second shielding loop, which generates a second compensating magnetic field that further compensates for at least a portion of the at least one of the first magnetic field and the second magnetic field, respectively, reducing the magnetic interference between the first and second filters.

17. The duplexer of claim 16, wherein the fourth conductor is the same as the third conductor.

18. The duplexer of claim 14, wherein each of the first filter and the second filter comprises a plurality of first film bulk acoustic resonators (FBARs) or bulk acoustic wave (BAW) resonators.

19. The duplexer of claim 14, wherein each of the transmit filter and the receive filter comprises a coupled resonator filter (CRF).

20. A magnetic shield for increasing isolation and reducing cross-talk between a transmit filter and a receive filter of a duplexer, mounted on a printed circuit board, the magnetic shield comprising:
a shielding bondwire shorted to a conductive layer of the printed circuit board between the transmit filter and the receive filter, the first shielding bondwire forming a closed electrical shielding loop, wherein a bondwire magnetic field generated by a bondwire connected to one of the transmit filter and the receive filter induces current in the shielding bondwire, which generates a compensating magnetic field that attenuates the bondwire magnetic field.
